(19) United States
(12) Patent Application Publication
(10) Pub. No.: US 2006/0262841 A1
(43) Pub. Date: Nov. 23, 2006

(54) Signal-to-interference power ratio estimator

(75) Inventors: Petri J. Vaisanen, Kempele (FI); Kari Pajukoski, Oulu (FI); Kari Horneman, Oulu (FI)

Correspondence Address: SQUIRE, SANDERS & DEMPSEY L.L.P., 14TH FLOOR, 8000 TOWERS CRESCENT, TYSONS CORNER, VA, 22182, US

(73) Assignee: Nokia Corporation

(21) Appl. No.: 11/177,288

(22) Filed: Jul. 11, 2005

(30) Foreign Application Priority Data
May 20, 2005 (FI) 20055229

(51) Int. Cl. H04B 17/00; H03D 1/04

(52) U.S. Cl. 375/227; 375/346

(57) ABSTRACT

A signal-to-interference power ratio (SIR) estimation method implementable in a telecommunication system is provided. The proposed SIR estimation method estimates SIR from received pilot symbols of a plurality of time intervals of a frame and is capable of taking into account different transmit powers of pilot symbols of different time intervals which would normally degrade the SIR estimate.

### FIELD

The invention relates to an estimator which estimates a power ratio between a desired signal and an interfering signal. The estimator may be implemented in a transceiver unit of a telecommunication system.

### BACKGROUND

In telecommunication systems, signal-to-interference power ratio (SIR) estimation is used, for example, for fast transmit power control in order to negate the effects caused by, for example, fast fading of a radio channel. In a universal mobile telecommunication System (UMTS), the SIR estimation is used in a base station in a so-called inner-loop power control in which an estimated SIR is compared to a target SIR and, if the estimated SIR is lower than the target SIR, a transmit power control command is transmitted to a subscriber unit for the subscriber unit to increase its transmit power. If the estimated SIR is higher than the target SIR, a transmit power control command is transmitted to a subscriber unit for the subscriber unit to decrease its transmit power in order not to interfere other users in the same frequency band.

The SIR estimation in a telecommunication system is usually based on pilot symbols transmitted over a radio channel. In a frame-structured telecommunication system, each frame comprises a plurality of time intervals (or time slots), and each time interval comprises a plurality of pilot symbols and a plurality of data symbols. Other types of symbols may also be transmitted in one time interval.

The pilot symbols are known by a receiver and, thus, the receiver may acquire knowledge of the radio channel by processing the pilot symbols. Usually there are only a few pilot symbols available for the SIR estimation, since SIR estimation is typically carried out on one time interval at a time. As an example, let us consider the SIR estimation for transmit power control of a UMTS in which one time slot of a frame comprises five to eight pilot symbols in a dedicated physical control channel (DPCCH). The number of pilot symbols in a time slot depends on the time slot format. Usually there are five or fewer pilot symbols available for the transmit power control SIR estimation due to implementational reasons. One such reason is that the transmit power control procedure is a fast procedure and, thus, the number of pilot symbols used for the transmit power control SIR estimation is limited. Limitation of the number of pilot symbols used for the SIR estimation reduces the accuracy of a SIR estimate, resulting in wrong transmit power control commands.

### BRIEF DESCRIPTION OF THE INVENTION

An object of the invention is to provide an improved solution for signal-to-interference power ratio estimation implemented in a transceiver unit of a telecommunication system which transfers frame-structured data with each frame comprising a plurality of time intervals, and each time interval comprising a plurality of pilot symbols.

According to an aspect of the invention, there is provided a signal-to-interference power ratio estimation method implemented in a first transceiver unit of a telecommunication system which transfers frame-structured data with each frame comprising a plurality of time intervals, and each time interval comprising a plurality of pilot symbols, the method comprising: receiving, from a second transceiver unit of the telecommunication system, a first and at least a second group of pilot symbols with each group being associated with different time interval. The method further comprises estimating a desired signal power using a determined number of pilot symbols from the first and at least the second group of pilot symbols with the estimation comprising removing the effect of transmit power control commands associated with each group of pilot symbols, estimating interference power using a determined number of pilot symbols from the first and at least the second group of pilot symbols with the estimation comprising removing the effect of transmit power control commands associated with each group of pilot symbols, and calculating a signal-to-interference power ratio by using the estimated desired signal power and the estimated interference power.

According to another aspect of the invention, there is provided a transceiver unit of a telecommunication system which transfers frame-structured data with each frame comprising a plurality of time intervals, each time interval comprising a plurality of pilot symbols. The transceiver unit comprises a communication interface to provide a communication link to another transceiver unit and a control unit configured to: receive, through the communication interface, a first and at least a second group of pilot symbols with each group being associated with a different time interval. The control unit is further configured to estimate a desired signal power using pilot symbols from the first and at least the second group of pilot symbols with the estimation comprising removing the effect of transmit power control commands associated with each group of pilot symbols, estimate interference power using pilot symbols from the first and at least the second group of pilot symbols with the estimation comprising removing the effect of transmit power control commands associated with each group of pilot symbols, and calculate a signal-to-interference power ratio by using the estimated desired signal power and the estimated interference power.

According to another aspect of the invention, there is provided a transceiver unit of a telecommunication system which transfers frame-structured data with each frame comprising a plurality of time intervals, each time interval comprising a plurality of pilot symbols. The transceiver unit comprises communication means to provide a communication link to another transceiver unit and means for receiving from a second transceiver unit a first and at least a second group of pilot symbols with each group being associated with a different time interval of a frame. The transceiver unit further comprises means for estimating a desired signal power using a determined number of pilot symbols from the first and at least the second group of pilot symbols with the estimation comprising removing the effect of transmit power control commands associated with each group of pilot symbols, means for estimating interference power using a determined number of pilot symbols from the first and at least the second group of pilot symbols with the estimation comprising removing the effect of transmit power control commands associated with each group of pilot symbols, and means for calculating a signal-to-interference power ratio by using the estimated desired signal power and the estimated interference power.

According to another aspect of the invention, there is provided a computer program product encoding a computer program of instructions for executing a computer process for signal-to-interference power ratio estimation implemented in a first transceiver unit of a telecommunication system which transfers frame-structured data with each frame comprising a plurality of time intervals, and each time interval comprising a plurality of pilot symbols. The process comprises receiving, from a second transceiver unit of the telecommunication system, a first and at least a second group of pilot symbols with each group being associated with a different time interval. The process further comprises estimating a desired signal power using a determined number of pilot symbols from the first and at least the second group of pilot symbols with the estimation comprising removing the effect of transmit power control commands associated with each group of pilot symbols, estimating interference power using a determined number of pilot symbols from the first and at least the second group of pilot symbols with the estimation comprising removing the effect of transmit power control commands associated with each group of pilot symbols and calculating a signal-to-interference power ratio by using the estimated desired signal power and the estimated interference power.

According to yet another aspect of the invention, there is provided a computer program distribution medium readable by a computer and encoding a computer program of instructions for executing a computer process for signal-to-interference power ratio estimation implemented in a first transceiver unit of a telecommunication system which transfers frame-structured data with each frame comprising a plurality of time intervals, and each time interval comprising a plurality of pilot symbols. The process comprises receiving, from a second transceiver unit of the telecommunication system, a first and at least a second group of pilot symbols with each group being associated with a different time interval. The process further comprises estimating a desired signal power using a determined number of pilot symbols from the first and at least the second group of pilot symbols with the estimation comprising removing the effect of transmit power control commands associated with each group of pilot symbols, estimating interference power using a determined number of pilot symbols from the first and at least the second group of pilot symbols with the estimation comprising removing the effect of transmit power control commands associated with each group of pilot symbols and calculating a signal-to-interference power ratio by using the estimated desired signal power and the estimated interference power.

The invention provides a significant advantage over prior art. Since the proposed solution is capable of using pilot symbols from a previous time interval or intervals, there are more pilot symbols available for SIR estimation. Additionally, the proposed solution is capable of taking into account different transmit powers of pilot symbols of different time intervals. Thus, the accuracy of a SIR estimate is improved. Consequently, performance of procedures which take advantage of the SIR estimate in a telecommunication system is improved.

### LIST OF DRAWINGS

In the following, the invention will be described in greater detail with reference to the embodiments and the accompanying drawings, in which

FIG. 1A illustrates a block diagram of a telecommunication system in which embodiments of the invention may be implemented;

FIG. 1B illustrates an example of a frame structure implemented in the telecommunication system of FIG. 1A;

FIG. 2 illustrates a block diagram of a transceiver unit in which embodiments of the invention may be implemented;

FIG. 3 illustrates a table structure implementable in SIR estimation according to an embodiment of the invention;

FIG. 4A illustrates an interference power estimation procedure according to an embodiment of the invention;

FIG. 4B illustrates a desired signal power estimation procedure according to an embodiment of the invention;

FIG. 5 illustrates a filter structure which may be implemented in interference power estimation according to an embodiment of the invention;

FIG. 6A illustrates an interference power estimation procedure in conjunction with a rake receiver according to an embodiment of the invention;

FIG. 6B illustrates a desired signal power estimation procedure in conjunction with a rake receiver according to an embodiment of the invention;

FIG. 6C illustrates a desired signal power estimation procedure in conjunction with a rake receiver according to another embodiment of the invention, and

FIG. 7 is a flow diagram illustrating a process for estimating a signal-to-interference power ratio according to an embodiment of the invention.

### DESCRIPTION OF EMBODIMENTS

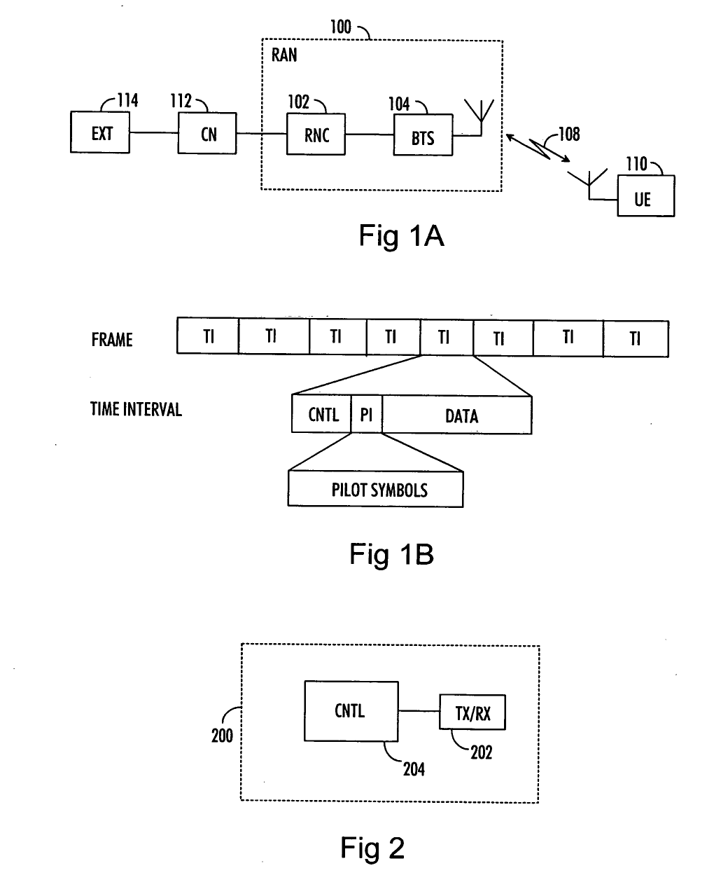

With reference to FIGS. 1A and 1B, examine an example of a communication system, in which embodiments of the invention may be applied. The structure and elements of the system illustrated in FIG. 1A are the same as in the Universal Mobile Telecommunication System (UMTS) network, but it should, however, be noted that implementation of the proposed data detection method is not limited to the UMTS system, but it may also be implemented in other suitable communication systems which employ frame-structured data transfer with each frame comprising a plurality of time intervals (or time slots), each time interval comprising a plurality of pilot symbols. Such a communication system may be, in addition to the UMTS system, for example another code division multiple access (CDMA)-based communication system, Wireless Local Area Network (WLAN) system or Global system for Mobile Communication (GSM).

The network elements of the communication system of FIG. 1A can be grouped into the radio access network (RAN) 100 that handles all radio-related functionalities of the system, and a core network (CN) 112, which takes care of switching and routing calls and data connections to external networks 114. The external network may be for example Internet, Integrated Services Digital Network (ISDN), or Public Switched Telephone Network (PSTN).

The radio access network 100 comprises one or several base transceiver stations (BTS) 104 and radio network controllers (RNC) 102. A BTS 104 is responsible for providing an air interface radio connection 108 to the subscriber units 110 within its coverage area also known as a cell. The BTS 104 also performs physical level signal processing like modulation, channel coding, etc. The BTS 104 may also perform some basic radio resource management operations like operations related to power control. Related to power control, the BTS 104 may estimate a signal-to-interference power ratio (SIR) from pilot symbols received from a subscriber unit.

A radio network controller 102 is the network element that is responsible for the control of radio resources in the RAN 100. The RNC 102 serves as a switching and controlling element of the RAN 100 and typically controls several BTSs 104, but it may also control only a single BTS 104. The RNC 102 is responsible for controlling the load and congestion of traffic channels of its own cells. The RNC 102 also takes care of procedures related to admission control, handovers, and power control. The radio network controller 102 typically includes a digital signal processor and software for executing computer processes stored on a computer readable medium. Furthermore, the radio network controller 102 typically includes connecting means for exchanging electric signals with other network elements, such as other radio network controllers and/or base transceiver stations, but also with the core network 112.

The core network 112 provides a combination of switching and transmission equipment, which together form a basis for telecommunication network services. The core network also performs procedures related to radio resource management. The core network 112 may provide circuit-switched and/or packet-switched data transport services to the user entities.

A simplified example of a frame structure of a communication system, in which embodiments of the invention may be applied, is illustrated in FIG. 1B. A detailed description of a frame has been omitted, since there may be different types of frame structures, and the present invention may be implemented in a telecommunication system employing various types of frame structures.

The frame of FIG. 1B comprises a plurality of time intervals (TI), and a time interval has a determined structure depending on the function of the time interval. A time interval of FIG. 1B comprises, along with data symbols and control symbols, a plurality of pilot symbols which may be used, for example, for signal-to-interference power ratio estimation or channel estimation in a receiver. The pilot symbols are known by the receiver.

Next, the structure of a transceiver unit 200 will be described with reference to FIG. 2. The transceiver unit 200 may be a subscriber unit of a communication system, such as a mobile communication device, or a computer with a communication interface to provide a radio connection. The transceiver unit may also be a network element of a communication system, such as a base transceiver station or an access point to a communication network.

The transceiver unit 200 comprises a communication interface 202 to receive in conjunction with an antenna information signals transmitted over a radio connection. If the transceiver unit 200 is a subscriber unit, the communication interface 202 may provide a connection with a communication network through a serving base transceiver station or an access point. The communication interface 202 may also provide capability to transmit information signals over a radio interface.

The transceiver unit 200 further comprises a control unit 204 to control functions of the transceiver unit 200. The control unit 204 may comprise means for retrieving information from a received signal. The retrieval procedure may comprise calculation of parameters of the received signal and adjusting operation of the transceiver unit 200 or another transceiver unit based on those parameters. The other transceiver unit may be, for example, the transceiver unit from which the signal was received. The calculation of parameters of the received signal may comprise calculation of SIR from the received signal. The control unit 204 may be implemented with a digital signal processor with suitable software embedded on a computer readable medium, or with separate logic circuits, for example with ASIC (Application Specific Integrated Circuit).

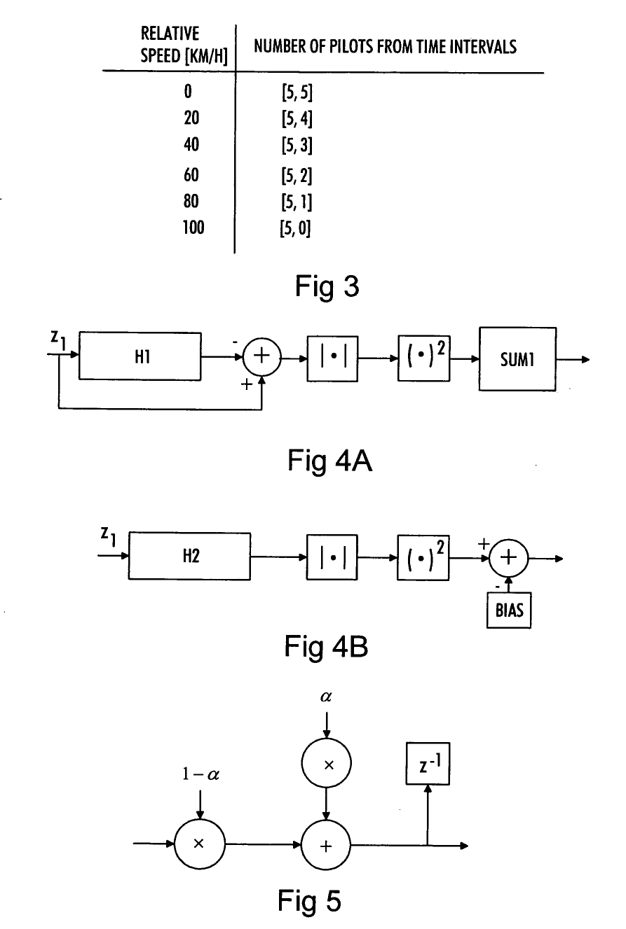

Next, a signal-to-interference power ratio (SIR) estimation according to an embodiment of the invention will be described with reference to FIGS. 3, 4A and 4B. The description of this embodiment is carried out using a least squares (LS) algorithm as an estimation algorithm for desired signal power estimation and a so-called minimum variance unbiased (MVU) estimator for interference power estimation, but it should be noted that the scope of the invention is not limited to the LS or MVU estimation algorithm, and any other suitable algorithm may be used in carrying out the SIR estimation.

The SIR estimator according to this embodiment of the invention estimates a SIR related to a communication between two transceiver units in a telecommunication system. The transceiver units may be a subscriber terminal and a base station serving the subscriber terminal. The SIR estimation may be carried out in either the base station or the subscriber terminal. The SIR estimation may also be carried out in both transceiver units.

As mentioned above, the SIR may be estimated from pilot symbols received in each time interval of a frame. The SIR estimation method according to an embodiment of the invention uses pilot symbols from multiple consecutive time intervals. A problem in using pilot symbols from multiple consecutive time intervals is that pilot symbols transmitted in different time intervals may be transmitted using different transmit powers, and if that is not taken into account, the result will be a SIR estimate with a degraded accuracy. The reason why different time intervals may be transmitted with different transmit powers may be, for example, the transmit power control implemented in the telecommunication system. The transmit power control commands for each time interval are, however, known in the telecommunication system and, thus, their effect may be taken into account as will be depicted next.

Let us consider a case where a first transceiver unit (a base station) is in communication with a second transceiver unit (a subscriber terminal). The first transceiver unit receives pilot symbols from the second transceiver unit. The pilot symbols may be received in multiple time intervals such that pilot symbols in different time intervals may be transmitted with different transmit powers. A received signal may be expressed as:
y=Ab+n, (1)
where A is a matrix representing transmit powers for each transmitted pilot symbol, b is a vector comprising the received pilot symbols and n is an interference vector. Since the pilot symbols are known by the first transceiver unit, the data modulation may be removed from the received pilot symbols by, for example, multiplying each known pilot symbol by its complex conjugate. Further, since transmit power control commands for each time interval are known by the first transceiver unit, equation (1) may be modified as:
z=hA+n, (2)
where z is a symbol vector resulting from removal of data modulation from y, A is a scalar parameter of received amplitude and h is a vector of known transmit amplitudes. h may be a column vector from an observation matrix H which comprises all the possible combinations of transmit power control commands related to the time intervals which are taken into account in the SIR estimation. For example, in a case where pilot symbols of two time intervals are taken into account in the SIR estimation, the observation matrix H may have the following structure:

$$H = {\{ \begin{matrix}1 - Δ & ⋯ & 1 - Δ & 1 & ⋯ & 1 \\ 1 + Δ & ⋯ & 1 + Δ & 1 & ⋯ & 1\end{matrix} \}}^{- 1} , \qquad ( 3 )$$

where Δ is a transmit power control step size and T denotes a transpose operation. In matrix H, the elements of the first column (i.e. the upper column) or vector having value 1−Δ are associated with pilot symbols of a first time interval and elements having value 1 are associated with pilot symbols of a second time interval following the first time interval. Thus, the first column represents a situation where transmit power control command has been ‘power up’. Accordingly, the second column (i.e. the lower column) of matrix H represents a situation where transmit power control command has been ‘power down’. The number of elements in a column represent how many pilot symbols are taken into account in the SIR estimation, and their values represent, how many pilot symbols from each time interval are taken into account in the SIR estimation. For example, if the first column of H comprises three elements with value 1−Δ and five elements with value 1, the SIR estimation will be carried out using three pilot symbols from the first time interval and five pilot symbols from the second time interval. The observation matrix H in a general form may have the following structure:

$$H = {\{ \begin{matrix}1 - L Δ & ⋯ & 1 - L Δ & ⋯ & 1 & ⋯ & 1 \\ ⋮ & & ⋮ & & ⋮ & & ⋮ \\ 1 + L Δ & ⋯ & 1 + L Δ & ⋯ & 1 & ⋯ & 1\end{matrix} \}}^{T} , \qquad ( 4 )$$

where L is the number of transmit power control commands included in matrix H, or the number of time intervals included in the SIR estimation minus one. As can be seen, the first column of H represents the situation in which all transmit power control commands have been ‘power up’ commands, and the last column represents the situation in which all transmit power control commands have been ‘power down’ commands. The columns in between include all possible combinations of transmit power control commands, the number of columns being 2^{L}. If two time intervals are included in the SIR estimation, the number of columns in matrix H is 2¹=2 (one for ‘power up’ command and one for ‘power down’ command), if three time intervals are included in the SIR estimation, the number of columns in matrix H is 2²=4 (one for ‘power up’-‘power up’, one for ‘power up’-‘power down’, one for ‘power down’-‘power up’, and one for ‘power down’-‘power down’), and so on.

The number of pilot symbols from each time interval, which is included in the SIR estimation, may be determined according to a determined criterion or criteria. A criterion may be, for example, the relative speed between a subscriber unit and a serving base station. The relative speed may be estimated for other purposes in the transceiver unit (for channel estimation purposes, for example), and that same relative speed estimate may be used for SIR estimation purposes, too. Alternatively, the relative speed may be estimated separately for SIR estimation purposes. The resulting estimate for relative speed may then be compared to a preset table in which relative speeds are associated with a number of pilot symbols for each time interval to be included in the signal-to-interference power ratio estimation. FIG. 3 illustrates an example of such a table. On the left hand side column there are relative speeds with which the speed estimate is compared. The speed estimate may be rounded, if the speed estimate does not precisely match with any speed in the table. When the proper speed has been determined from the table, the number of pilot symbols from each time interval is determined from the right hand side column of the table. The right hand side column of the table of FIG. 3 comprises numbers indicating how many pilot symbols from the current time interval and from the time interval previous to the current time interval are included in the SIR estimation. The term ‘current time interval’ refers to a time interval which has not yet been included in the SIR estimation but which is next in line to be included in the SIR estimation. For example, if a relative speed estimate is 15 km/h, the estimate is first rounded up to 20 km/h to match a closest relative speed in the table. Then, the proper number of pilot symbols associated with the speed of 20 km/h is retrieved from the right hand side column. The proper number of pilot symbols is [5, 4], which means that 5 pilot symbols from the current time interval and 4 pilot symbols from the previous time interval are included in the SIR estimation.

In the above example, the same number of pilot symbols is used for both the desired signal power estimation and the interference power estimation. Alternatively, a different number of pilot symbols may be used for the desired signal power estimation and interference power estimation. In this case, the table may comprise information on how many pilot symbols from each time interval are included in the desired signal power estimation and in the interference power estimation separately. In some situations, it may be suitable to use more pilot symbols for the interference power estimation than for the desired signal power estimation. In some environments, the interference power level does not change as rapidly as the desired signal power level, and then it may be suitable to use more pilot symbols for the interference power estimation in order to improve accuracy of the estimate.

Next, the estimation of interference power and desired signal power according to an embodiment of the invention will be described with reference to FIGS. 4A and 4B.

FIG. 4A illustrates an operational block diagram of interference estimation according to an embodiment of the invention. Interference power may be estimated using the following equation:

$${\hat{σ}}_{n}^{2} = \frac{1}{K - 1} {I}^{T} ( {\vert z - {h ( {h}^{T} h )}^{- 1} {h}^{T} z \vert}^{2} ) , \qquad ( 5 )$$

where K is the number of pilot symbols included in the estimation, i.e. the length of all the vectors of equation (7), I is a unity column vector as:
I=[1 1 . . . 1]^{T}, (6)
h is a column vector comprising power levels of the pilot symbols included in the interference power estimation, and |. | denotes an absolute value operation. Referring to FIG. 4A, an input vector to the interference estimator is z₁ which has the same structure as vector z in equation (2). The first operation is to multiply the received vector z₁ by the result of operation h(h^{T}h)⁻¹ h^{T} (denoted with operator H1 in FIG. 4A). The result of the multiplication is a vector comprising ensemble average values of the vector z₁. The ensemble average vector is then subtracted from the original vector z₁. An absolute value is then taken from the resulting vector of the subtraction and the absolute value vector is squared. Then, the squared vector is multiplied by the unity vector I. This operation corresponds to summing up the elements of the squared vector. The result is then divided by K−1 (the multiplication by the unity vector and the division is denoted with operator SUM1 in FIG. 4A) in order to obtain an estimate for interference power. The interference estimator of the above equation (4) is a so-called minimum variance unbiased estimator.

FIG. 4B illustrates an operational block diagram of desired signal estimation according to an embodiment of the invention. The desired signal power may be estimated using the following equation:
\hat{A}²=|(h^{T}h)⁻¹h^{T}z₁|²−(h^{T}h)⁻¹\hat{σ}ₙ² (7)

Referring to FIG. 4B, an input vector to the estimator is again z₁. The first operation is to multiply the received vector z₁ by the result of operation (h^{T}h)⁻¹h^{T} (denoted with operator H2 in FIG. 4B). Operation (h^{T}h)⁻¹h^{T} may be calculated for each column of matrix H in advance in order to reduce real-time computational complexity. An absolute value is then taken from the resulting vector and the absolute value vector is squared. This result is a so-called LS-estimate of the desired signal power, but it is, however, a biased estimate. Thus, the result (denoted with operator BIAS in FIG. 4B) of the multiplication operation between (h^{T}h)⁻¹ and the interference estimate calculated as described with reference to equation (4) is subtracted from the LS-estimate in order to obtain an unbiased estimate for the desired signal power.

In order to obtain the SIR estimate using the estimated interference power and the estimated desired signal power, the estimated desired signal power may be divided with the interference power.

According to another embodiment of the invention, a desired signal power estimate is calculated non-coherently by estimating a signal power by calculating a desired signal power for each time interval separately and then calculating a total estimate for desired signal power by using these estimates.

Now, the estimation of desired signal power for one time interval will be described. Since the desired signal power is calculated for one time interval at a time, equation (2) simplifies to:
zₖ=IAₖ+nₖ, (8)
where I is a single column unity vector.

As can be seen, equation (8) includes index k in order to discriminate processing of different time intervals. This was not necessary in equation (2), since multiple time intervals were processed jointly. Again, I is a unity column vector, and the length of vector I is the same as the number of pilot symbols included in the estimation of the desired signal power of the time interval. The simplification of equation (2) results from the fact that the pilot symbols of one time interval are transmitted with the same transmit power and, thus, there is no need to compensate for the transmit power differences. An intermediate estimate for desired signal power of the k^{th} time interval is calculated according to the following equation:

$${\hat{A}}_{k}^{2} = {\vert \frac{1}{N} {I}^{T} {z}_{k} \vert}^{2} - \frac{{{σ}^{⋒}}_{n}^{2}}{N} , \qquad ( 9 )$$

where N is the number of pilot symbols included in the calculation, and \hat{σ}ₙ² is the interference power estimate calculated according to equation (5), for example. Let us assume that M time intervals are included in the SIR estimation. Then, intermediate desired signal powers of M time intervals are estimated according to equation (9), and a vector comprising these desired signal power estimates is formed as:
Â_{k-M:k}²=[Â_{k-M}². . . Âₖ²]^{T}. (10)

Now, a total desired signal power estimate may be calculated according to the following equation:
Â_{k-M:k}²=(h_{k-M:k}^{T}h_{k-M:k})⁻¹h_{k-M:k}^{T}Â_{k-M:k}^{e}². (11)

In equation (11), vector h is again selected from the observation matrix H to represent the power control commands related to the time intervals included in the calculation of the total desired signal estimate. It should be noticed that in this embodiment matrix H comprises only one element representing each power control command as:

$$H = [ \begin{matrix}1 - L Δ & ⋯ & 1 - Δ & 1 \\ ⋮ & ⋮ & ⋮ & ⋮ \\ 1 + L Δ & ⋯ & 1 + Δ & 1\end{matrix} ] . \qquad ( 12 )$$

This results from the fact that intermediate desired signal power estimates are now used instead of pilot symbols for calculation of the total desired signal power estimate. In equation (11), the effects of transmit power control commands are removed from the intermediate desired signal power estimates and an average desired signal power is calculated.

According to another embodiment of the invention, the interference power estimate may be calculated recursively such that previous interference estimates are also taken into account when calculating a current interference estimate. The current interference estimate may be processed according to the following equation:
y_{σ}(n)=α·y_{σ}(n−1)+(1−α)·\hat{σ}ₙ²(n), (13)
where α is a so-called forgetting factor which describes the weight of the previous interference estimates, y_{σ} is a result of the equation and \hat{σ}ₙ²(n) is the current interference power estimate calculated according to the above equation (5). The forgetting factor a may be chosen according to the properties of the radio channel. In an environment where the interference power level is likely to change rapidly, it is suitable to select a small value for α. On the other hand, it is suitable to select a large value for α in an environment where the interference level is likely to change slowly. Then, previous estimates for interference level will have more effect on the current SIR estimate. FIG. 5 illustrates a filter structure which may be used for carrying out the processing of the interference estimate according to the above equation (5).

In the above with reference to FIG. 3, it was stated that the number of pilot symbols from each time interval, which is included in the SIR estimation, may be determined according to a determined criterion or criteria. It was also stated that the criterion may be the estimated relative speed between a subscriber unit and a base station. Instead of using the estimated relative speed as a criterion, the SIR estimation may be carried out using various combinations of numbers of pilot symbols from each time interval, and selecting the combination which provides the most accurate SIR estimate. For example, combinations of pilot symbols from which SIR estimates are calculated may be those illustrated in the right hand side of the table in FIG. 3 ([5, 5]; [5, 4]; [5, 3]; [5, 2]; [5, 1]; [5, 0]). From each of the combinations of pilot symbols, the SIR estimate may be calculated by using, for example, equations (5) and (7), thus yielding six SIR estimates. The most accurate SIR estimate may then be selected according to a criterion. The criterion may be based on selecting the SIR estimate with the lowest variance. The variance for each SIR estimate may be calculated by using a state-of-the-art variance estimator.

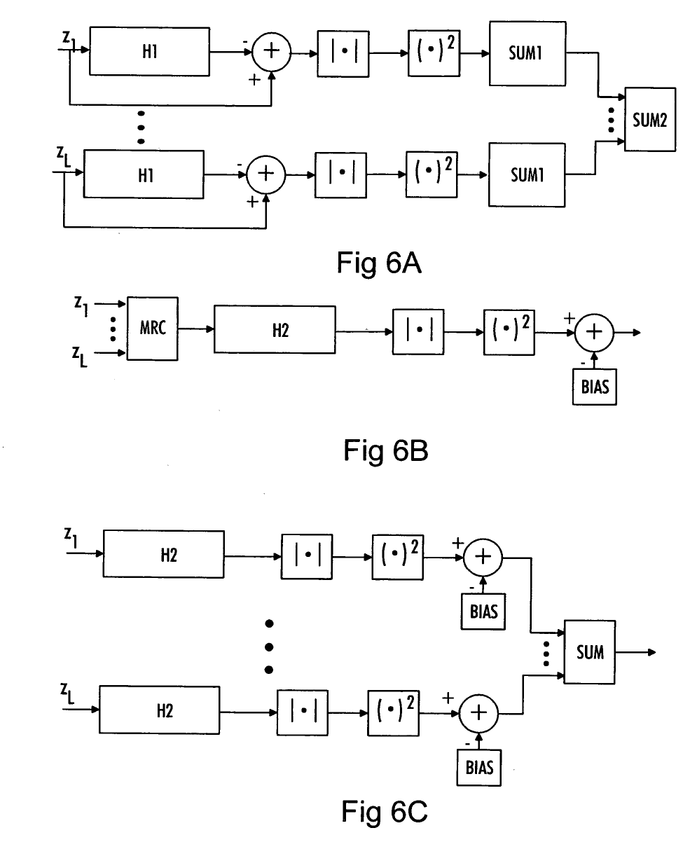

Next, a SIR estimation algorithm according to another embodiment of the invention will be described with reference to FIGS. 6A and 6B. A transceiver unit according to this embodiment comprises a rake receiver, and properties of the rake receiver are used in the SIR estimation. FIG. 6A illustrates an interference power estimator which calculates an interference power estimate for each rake receiver finger, i.e. for each resolvable signal path of a radio channel. Input pilot symbol vector z₁ in FIG. 6A refers to pilot symbol components received through a first signal path and input pilot symbol vector z_{L} refers to pilot symbol components received through the L^{th} signal path. Interference power may be estimated from each of these input vectors using, for example, equation (5) as illustrated in FIG. 6A. After calculating interference power estimates related to each resolvable signal path, a mean value may be taken from these interference power estimates in order to obtain a total interference power estimate. By calculating the interference power estimate for each resolvable signal path, it is possible to improve the accuracy of the estimate, since there is more information available on the interfering environment than there would be if only one signal path were considered or if the pilot symbol components were combined prior to the interference power estimation.

FIG. 6B illustrates a desired signal power estimator which calculates an estimate for desired signal power after combining the rake receiver fingers. The pilot symbol components of each input pilot symbol vector z₁ to z_{L} may be combined using, for example, maximal ratio combining (MRC) prior to the desired signal power estimation. Equivalently, any other combining technique may be implemented instead of MRC. After combining the components of each pilot symbol included in the desired signal power estimation, the desired signal power may be estimated according to equation (7) as illustrated in FIG. 6B. By combining the pilot symbol components prior to the desired signal power estimation, it is possible to improve the accuracy of the estimate. It is well known that MRC amplifies strong signal paths while attenuating weak signal paths. Thus, after combining, the signal-to-noise ratios (SNR) of the pilot symbols included in the estimation are higher than the SNRs of the pilot symbol components prior to the combining, and therefore the estimate is more accurate.

FIG. 6C illustrates another embodiment for a desired signal power estimator. According to this embodiment, desired signal power is estimated for each pilot symbol vectors z₁ to z_{L} separately. The desired signal power estimation may be carried out according to equation (7) as illustrated in FIG. 6C. Then, the desired signal power estimates may be combined in order to obtain a combined estimate of the desired signal power. The combination may be based on a simple summation of the L estimates, for example. This combination corresponds to an equal gain combining procedure.

According to another embodiment of the invention, data symbols are included in the SIR estimation together with pilot symbols. The data symbols may comprise control data symbols and/or information data symbols. If the data symbols included in the SIR estimation are not known by the transceiver unit where the SIR estimation is carried out, data detection is performed on the data symbols. When data detection has been completed, the data modulation may be removed from the data symbols to be included in the SIR estimation, and these data symbols may be used in the SIR estimation as pilot symbols. This means that their transmit power levels may be taken into account in the observation matrix H and they may be included in the symbol vector z.

The SIR estimation according any embodiment described above may be carried out in a transceiver unit, which may be a base station or a subscriber unit. The SIR estimate may be used for power control purposes, either uplink power control or downlink power control. The SIR estimate may be compared to a target value for SIR, and if the SIR estimate is lower that the target SIR, a command to increase the transmit power may be transmitted to the transceiver unit from which the pilot symbols used in the SIR estimation were received. On the other hand, if the SIR estimate is higher than the target SIR, a command to decrease the transmit power may be transmitted.

In addition to power control, the SIR estimates may be used for configuring parameters of the transceiver unit which estimated the SIR or the transceiver unit which had transmitted the symbols (pilot symbols and/or data symbols). The SIR estimate is an estimate of the state of a radio channel and, thus, it may be used in, for example, adaptive modulation, data packet scheduling, admission control, or in estimation of the load of the communication network. In adaptive modulation, the SIR estimate may be used in determining the type of modulation used in data transmission. Again, the SIR estimate may be compared to a target SIR, and if the estimated SIR is lower than the target SIR, the modulation type may be switched to one with a better error tolerance and perhaps a lower data rate, for example. On the other hand, if the estimated SIR is higher than the target SIR, modulation type may be switched to one with higher data rate but poorer error tolerance. A hysteresis may be provided in the target SIR to avoid rapid switching between the modulation schemes. In packet scheduling, the SIR estimate may be used for determining the channel state. Again, the SIR estimate may be compared to a target SIR, and if the estimated SIR is lower than the target SIR, it is considered that load of the communication network is high and the scheduling rate of data packets into the channel is reduced. On the other hand, if the estimated SIR is higher than the target SIR, the packet scheduling rate may be increased. Equivalently in admission control, the estimated SIR may be used in determining whether available radio resources will be allocated for a service requesting radio resources. Again, the SIR estimate may be compared to a target SIR, and if the estimated SIR is lower than the target SIR, no available radio resources will be allocated for the service requesting radio resources in order not to degrade the quality of other services. On the other hand, if the estimated SIR is higher than the target SIR, available radio resources may be allocated for the service requesting radio resources. Naturally, the SIR estimate may be used in other ways than just simply for comparing the SIR estimate to the target SIR in the above functions of a telecommunication system. Additionally, criteria other than SIR may also have an effect on actions of the above functions. For example, the bit error rate together with the SIR estimate may have an effect on whether or not to change the modulation scheme in adaptive modulation.

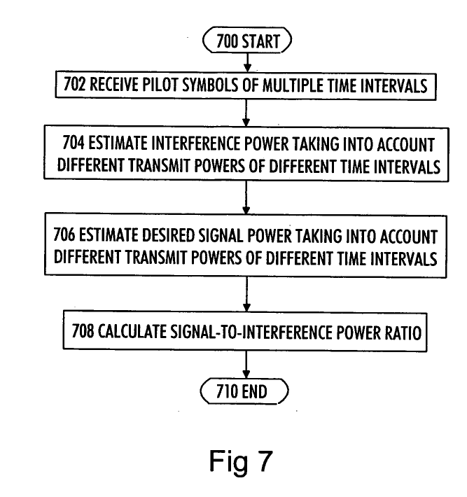

Next, a process for SIR estimation according to an embodiment of the invention will be described with reference to a flow diagram of FIG. 7. The process starts in step 700. A first transceiver unit receives pilot symbols from a second transceiver unit in multiple time intervals in step 702. Using the received pilot symbols, interference power is estimated in step 704. The estimation takes into account different transmit powers of pilot symbols associated with different time intervals. The estimation may be carried out using a suitable estimation algorithm, for example the algorithm of equation (5).

Using the received pilot symbols, desired signal power is estimated in step 706. The estimation takes into account different transmit powers of pilot symbols associated with different time intervals. The estimation may be carried out using a suitable estimation algorithm, for example the algorithm of equation (7).

Signal-to-interference power ratio is calculated in step 708. The SIR may be calculated by dividing the desired signal power estimate by the interference power estimate. The process ends in step 710.

The transceiver unit of the type described above may be used for implementing the method, but also other types of transceiver units may be suitable for the implementation. In an embodiment, a computer program product encodes a computer program of instructions for executing a computer process of the above-described method of signal-to-interference power ratio estimation. The computer program product may be implemented on a computer program distribution medium. The computer program distribution medium includes all manners known in the art for distributing software, such as a computer readable medium, a program storage medium, a record medium, a computer readable memory, a computer readable software distribution package, a computer readable signal, a computer readable telecommunication signal, and a computer readable compressed software package.

Even though the invention has been described above with reference to an example according to the accompanying drawings, it is clear that the invention is not restricted thereto but it can be modified in several ways within the scope of the appended claims.

1. A signal-to-interference power ratio estimation method implemented in a first transceiver unit of a telecommunication system which transfers frame-structured data with each frame comprising a plurality of time intervals and each time interval comprising a plurality of pilot symbols, the method comprising:
receiving, from a second transceiver unit of the telecommunication system, a first and at least a second group of pilot symbols with each group being associated with different time interval;
estimating the desired signal power using a determined number of pilot symbols from the first and at least the second group of pilot symbols, wherein an estimation of the desired signal power comprises removing an effect of transmit power control commands associated with each group of pilot symbols;
estimating interference power using the determined number of pilot symbols from the first and at least the second group of pilot symbols, wherein an estimation of interference power comprises removing the effect of transmit power control commands associated with each group of pilot symbols; and
calculating a signal-to-interference power ratio by using an estimated desired signal power and an estimated interference power.

2. The method of claim 1, further comprising using the signal-to-interference power ratio estimation for controlling a transmit power of the second transceiver unit.

3. The method of claim 1, further comprising:
using the signal-to-interference power ratio estimation for estimating a state of a radio channel; and
configuring parameters of the first transceiver unit according to a radio channel state estimate.

4. The method of claim 1, further comprising receiving the first and at least the second group of pilot symbols in consecutive time intervals.

5. The method of claim 1, wherein estimating the desired signal power comprises:
estimating intermediate desired signal powers separately for the time intervals associated with the received first and at least second group of pilot symbols; and
estimating the desired signal power from the intermediate desired signal powers, wherein estimating the desired signal power comprising removing the effect of transmit power control commands associated with each group of pilot symbols.

6. The method of claim 1, further comprising:
receiving a plurality of data symbols in at least one time interval;
removing data modulation from the received plurality of data symbols after data detection of the received plurality of data symbols; and
using the plurality of data symbols from which data modulation has been removed, in addition to the pilot symbols, in the signal power estimation and the interference power estimation.

7. The method of claim 1, further comprising:
determining, for each time interval, a number of pilot symbols to be used in the signal-to-interference power ratio estimation based on an estimate of relative speed between the first transceiver unit and the second transceiver unit; and
selecting the determined number of pilot symbols from each time interval for the signal-to-interference power ratio estimation.

8. The method of claim 7, wherein the determination comprises comparing an estimated relative speed between the first transceiver unit and the second transceiver unit with a preset table, in which the relative speeds between the first transceiver unit and the second transceiver unit are associated with a number of pilot symbols for each time interval to be included in the signal-to-interference power ratio estimation.

9. The method of claim 1, further comprising:
receiving the first and at least the second group of pilot symbols using a rake receiver;
estimating the interference power for each rake receiver finger; and
combining the estimates of the interference power for each rake receiver finger.

10. The method of claim 9, further comprising:
combining rake receiver fingers, thus producing combined received pilot symbols; and
estimating the desired signal power from the combined received pilot symbols.

11. The method of claim 9, further comprising:
estimating the desired signal power for each rake receiver finger; and
combining the estimates of the desired signal power for each rake receiver finger.

12. The method of claim 1, further comprising taking into account previous interference power estimates when calculating the current interference power estimate.

13. The method of claim 1, wherein the calculation of the signal-to-interference power ratio comprises dividing the estimated desired signal power by the estimated interference power.

14. A transceiver unit of a telecommunication system which transfers frame-structured data with each frame comprising a plurality of time intervals, each time interval comprising a plurality of pilot symbols, the transceiver unit comprising:
a communication interface to provide a communication link to another transceiver unit;
a control unit configured to:
receive, through the communication interface, a first and at least a second group of pilot symbols with each group being associated with a different time interval;
estimate a desired signal power using pilot symbols from the first and at least the second group of pilot symbols, wherein an estimation of the desired signal power comprises removing the effect of transmit power control commands associated with each group of pilot symbols;
estimate interference power using pilot symbols from the first and at least the second group of pilot symbols, wherein an estimation of interference power comprises removing the effect of transmit power control commands associated with each group of pilot symbols, and
calculate a signal-to-interference power ratio by using an estimated desired signal power and an estimated interference power.

15. The transceiver unit of claim 14, wherein the control unit is further configured to use the signal-to-interference power ratio estimation for controlling a transmit power of a second transceiver unit.

16. The transceiver unit of claim 14, wherein the control unit is further configured to:
use the signal-to-interference power ratio estimate for estimating a state of a radio channel; and
configure parameters of a first transceiver unit according to an estimated state of the radio channel.

17. The transceiver unit of claim 14, wherein the control unit is further configured to receive the first and at least the second group of pilot symbols in consecutive time intervals.

18. The transceiver unit of claim 14, wherein the control unit is configured to carry out estimation of the desired signal power by:
estimating intermediate desired signal powers separately for time intervals associated with the received first and at least second group of pilot symbols; and
estimating the desired signal power from the intermediate desired signal powers with the estimation comprising removing the effect of transmit power control commands associated with each group of pilot symbols.

19. The transceiver unit of claim 14, wherein the control is being further configured to:
receive, through the communication interface, a plurality of data symbols in at least one time interval;
remove data modulation from the received plurality of data symbols after data detection; and
use the plurality of data symbols from which data modulation has been removed, in addition to the pilot symbols, in signal power and interference power estimation.

20. The transceiver unit of claim 14, wherein the control unit is further configured to:
determine, for each time interval, a number of pilot symbols to be used in a signal-to-interference power ratio estimation based on an estimate of relative speed between a first transceiver unit and a second transceiver unit; and
select the determined number of pilot symbols from each time interval for the signal-to-interference power ratio estimation.

21. The transceiver unit of claim 20, wherein the control unit is further configured to compare an estimated relative speed between the first transceiver unit and the second transceiver unit with a preset table, in which relative speeds between the first and the second transceiver unit are associated with a number of pilot symbols for each time interval to be included in the signal-to-interference power ratio estimation.

22. The transceiver unit of claim 14, wherein the control unit is further configured to:
receive the first and at least a second group of pilot symbols using a rake receiver;
estimate the interference power for each rake receiver finger; and
combine the estimates of the interference power for each rake receiver finger.

23. The transceiver unit of claim 22, wherein the control unit is further configured to:
combine rake receiver fingers, thus producing combined received pilot symbols; and
estimate the desired signal power from the combined received pilot symbols.

24. The transceiver unit of claim 22 wherein the control unit is further configured to:
estimate the desired signal power for each rake receiver finger; and
combine the estimates of the desired signal power for each rake receiver finger.

25. The transceiver unit of claim 14, wherein the control unit is further configured to use previous interference power estimates when calculating a current interference power estimate.

26. The transceiver unit of claim 14, wherein the control unit is further configured to calculate a signal-to-interference power ratio by dividing the estimated desired signal power by the estimated interference power.

27. A transceiver unit of a telecommunication system which transfers frame-structured data with each frame comprising a plurality of time intervals, each time interval comprising a plurality of pilot symbols, the transceiver unit comprising:
communication means to provide a communication link to another transceiver unit;
means for receiving from a second transceiver unit a first and at least a second group of pilot symbols with each group being associated with a different time interval of a frame;
means for estimating a desired signal power using a determined number of pilot symbols from the first and at least the second group of pilot symbols, wherein estimation of the desired signal power comprises removing the effect of transmit power control commands associated with each group of pilot symbols;
means for estimating interference power using a determined number of pilot symbols from the first and at least the second group of pilot symbols, wherein estimation of the interference power comprises removing the effect of transmit power control commands associated with each group of pilot symbols, and
means for calculating a signal-to-interference power ratio by using an estimated desired signal power and an estimated interference power.

28. A computer program product embodied on a computer readable medium, the computer program product encoding a computer program of instructions for executing a computer process for signal-to-interference power ratio estimation implemented in a first transceiver unit of a telecommunication system which transfers frame-structured data with each frame comprising a plurality of time intervals, and each time interval comprising a plurality of pilot symbols, the process comprising:
receiving, from a second transceiver unit of the telecommunication system, a first and at least a second group of pilot symbols with each group being associated with a different time interval;
estimating a desired signal power using a determined number of pilot symbols from the first and at least the second group of pilot symbols with the estimation comprising removing the effect of transmit power control commands associated with each group of pilot symbols;
estimating interference power using a determined number of pilot symbols from the first and at least the second group of pilot symbols with the estimation comprising removing the effect of transmit power control commands associated with each group of pilot symbols and
calculating a signal-to-interference power ratio by using the estimated desired signal power and the estimated interference power.

29. A computer program distribution medium readable by a computer and encoding a computer program of instructions for executing a computer process for signal-to-interference power ratio estimation implemented in a first transceiver unit of a telecommunication system which transfers frame-structured data with each frame comprising a plurality of time intervals, and each time interval comprising a plurality of pilot symbols, the process comprising:
receiving, from a second transceiver unit of the telecommunication system, a first and at least a second group of pilot symbols with each group being associated with a different time interval;
estimating a desired signal power using a determined number of pilot symbols from the first and at least the second group of pilot symbols with the estimation comprising removing the effect of transmit power control commands associated with each group of pilot symbols;
estimating interference power using a determined number of pilot symbols from the first and at least the second group of pilot symbols with the estimation comprising removing the effect of transmit power control commands associated with each group of pilot symbols and
calculating a signal-to-interference power ratio by using the estimated desired signal power and the estimated interference power.

30. The computer program distribution medium of claim 29, the distribution medium comprising at least one of the following mediums: computer readable medium, a program storage medium, a record medium, a computer readable memory, a computer readable software distribution package, a computer readable signal, a computer readable telecommunications signal, and a computer readable compressed software package.
